(19) United States
(12) Patent Application Publication
(10) Pub. No.: US 2026/0206168 A1
(43) Pub. Date: Jul. 16, 2026

(54) POWER MODULE AND ELECTRICAL DEVICE

(71) Applicant: SUNGROW POWER SUPPLY CO., LTD., Hefei (CN)

(72) Inventors: Hao ZHENG, Hefei (CN); Xiaohu WANG, Hefei (CN); Guofeng ZHANG, Hefei (CN); Qiyao ZHU, Hefei (CN); Xiang GAO, Hefei (CN)

(21) Appl. No.: 19/565,608

(22) Filed: Mar. 13, 2026

Related U.S. Application Data
(63) Continuation of application No. PCT/CN2024/080887, filed on Mar. 11, 2024.

(30) Foreign Application Priority Data
Sep. 15, 2023 (CN) 202322525650.5

(51) Int. Cl. H05K 7/14; H05K 7/20

(52) U.S. Cl. CPC H05K 7/14324; H05K 7/209

(57) ABSTRACT

A power module and an electrical device are provided, belonging to the field of electrical device technologies. The power module includes: a base provided with a plurality of mounting parts and a first sliding structure configured to be slidably engaged with a cabinet, each of the plurality of mounting parts being provided with a second sliding structure; and a plurality of module bodies, each of the plurality of module bodies being provided with a third sliding structure slidably engaged with the second sliding structure, the plurality of module bodies being adapted to be mounted at the plurality of mounting parts via the third sliding structures, respectively.

### CROSS-REFERENCE TO RELATED APPLICATION

This application is a continuation of International Application No. PCT/CN2024/080887, filed on March 11, 2024, which is based on and claims priority to Chinese Patent Application No. 202322525650.5 filed on September 15, 2023, the entire contents of which are incorporated herein by reference.

### FIELD

The present disclosure relates to the field of electrical device technologies, and more particularly, to a power module and an electrical device.

### BACKGROUND

Existing electrical device generally adopts a plurality of independent power modules. These power modules require periodic maintenance and replacement throughout the lifecycle of the electrical device. When maintenance is required, the power modules are generally replaced by plugging and unplugging. The power modules are mounted in the cabinet of the electrical device with the aid of guide rails. However, in practical applications, when the plurality of power modules require maintenance, the plurality of power module can be disassembled and replaced individually in sequence. In the case of overall maintenance requirements, this individual replacement method makes the maintenance overly complex, which significantly increases the operation time of relevant operators during power module maintenance, resulting in unnecessary waste of labor costs.

### SUMMARY

The present disclosure aims to solve at least one of the technical problems in the related art. To this end, the present disclosure provides a power module and an electrical device.

In a first aspect, the present disclosure provides a power module. The power module includes: a base provided with a plurality of mounting parts and a first sliding structure configured to be slidably engaged with a cabinet, each of the plurality of mounting parts being provided with a second sliding structure; and a plurality of module bodies, each of the plurality of module bodies being provided with a third sliding structure slidably engaged with the second sliding structure, the plurality of module bodies being adapted to be mounted at the plurality of mounting parts via the third sliding structures, respectively.

In a second aspect, the present disclosure provides an electrical device. The electrical device includes: the power module according to any one of the above-described embodiments; and a cabinet having a mounting groove, a fourth sliding structure being disposed in the mounting groove, the first sliding structure being slidably engaged with the fourth sliding structure, the power module being mounted in the mounting groove, and the base being detachably connected to the cabinet.

Additional aspects and advantages of the present disclosure will be provided in part in the following description, or will become apparent in part from the following description, or can be learned from practicing of the present disclosure.

### BRIEF DESCRIPTION OF THEDRAWINGS

The above and/or additional aspects and advantages of the present disclosure will become more apparent and more understandable from the following description of embodiments taken in conjunction with the accompanying drawings.

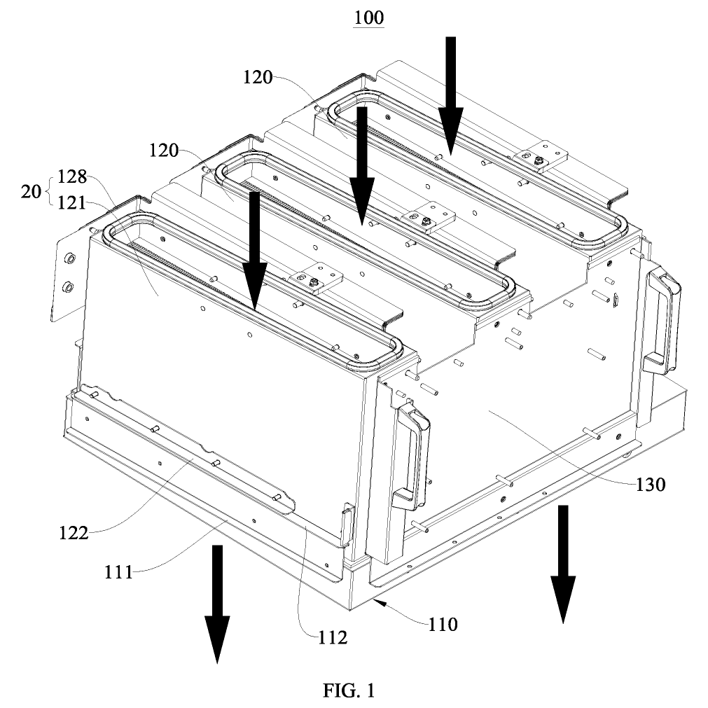

FIG. 1 is a schematic structural view of a power module according to an embodiment of the present disclosure.

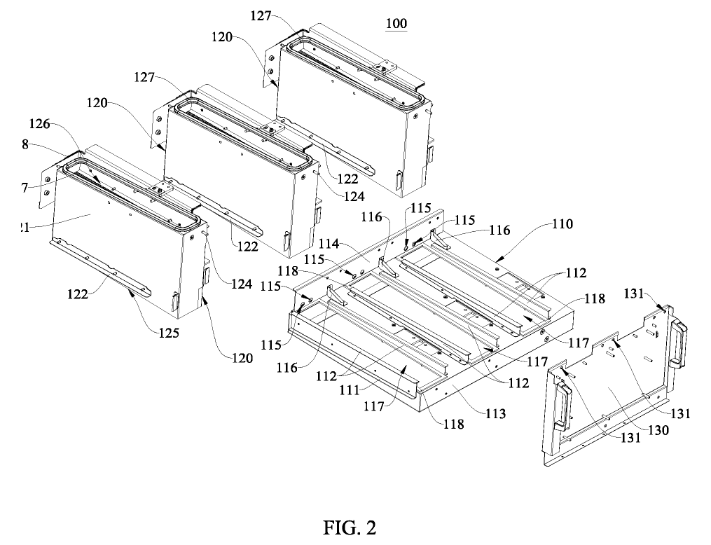

FIG. 2 is a first exploded schematic view of a power module according to an embodiment of the present disclosure.

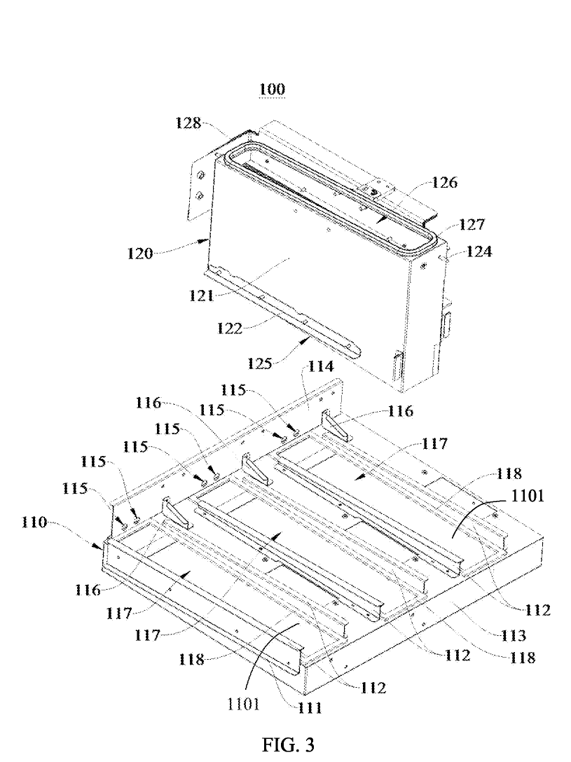

FIG. 3 is a second exploded schematic view of a power module according to an embodiment of the present disclosure.

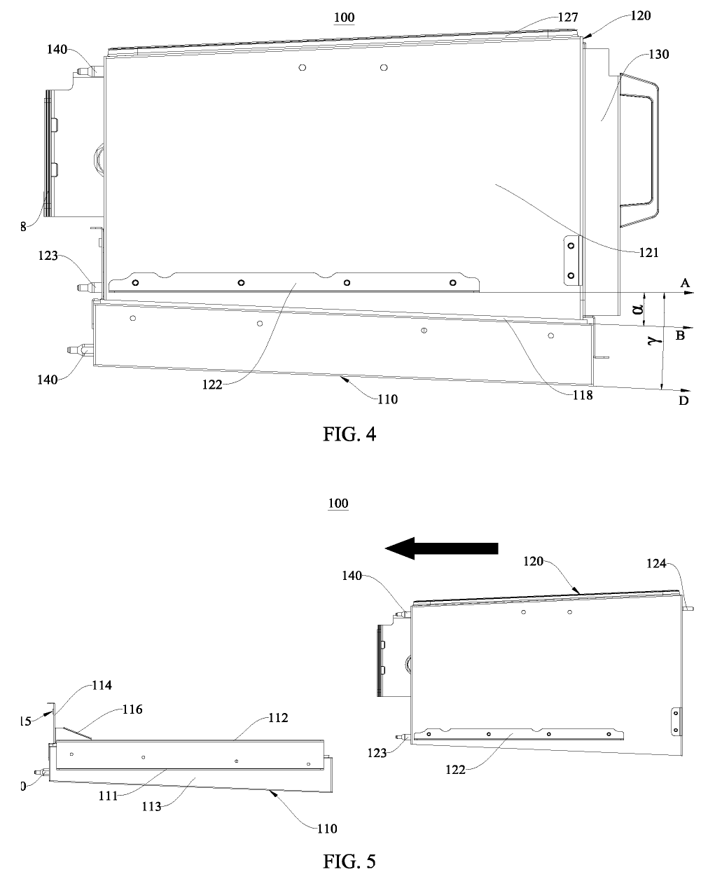

FIG. 4 is a side view of a power module according to an embodiment of the present disclosure.

FIG. 5 is a first schematic assembly view of a power module according to an embodiment of the present disclosure.

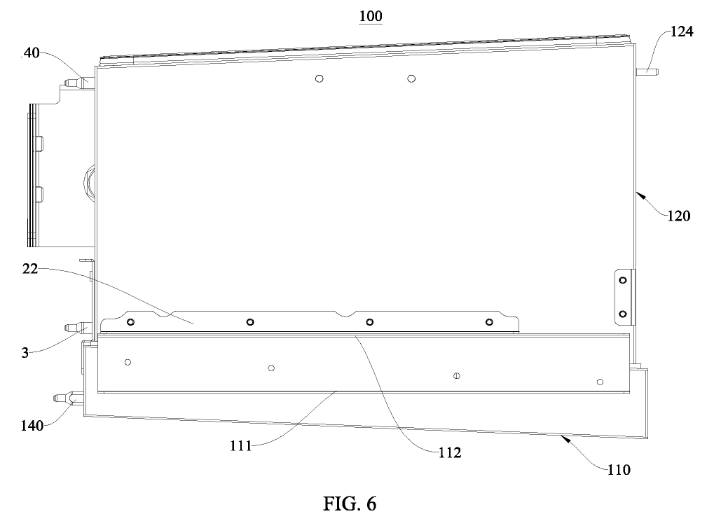

FIG. 6 is a second schematic assembly view of a power module according to an embodiment of the present disclosure.

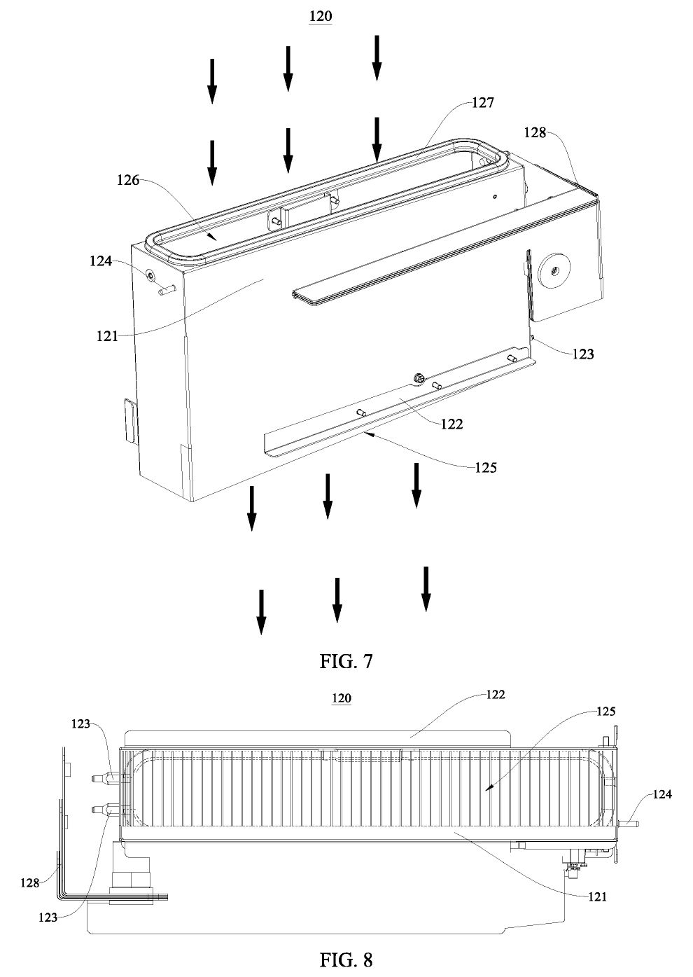

FIG. 7 is a schematic structural view of a module body according to an embodiment of the present disclosure.

FIG. 8 is a bottom view of a module body according to an embodiment of the present disclosure.

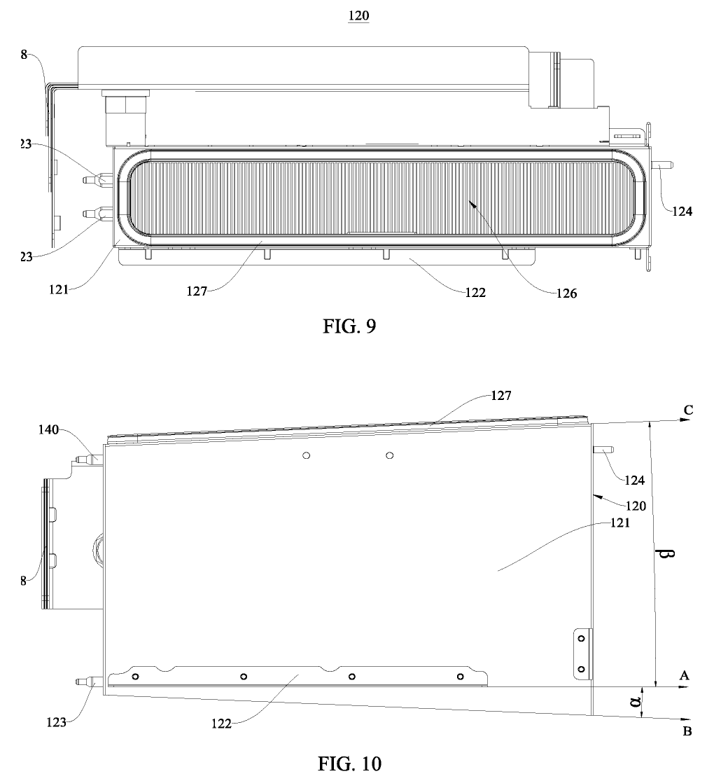

FIG. 9 is a top view of a module body according to an embodiment of the present disclosure.

FIG. 10 is a side view of a module body according to an embodiment of the present disclosure.

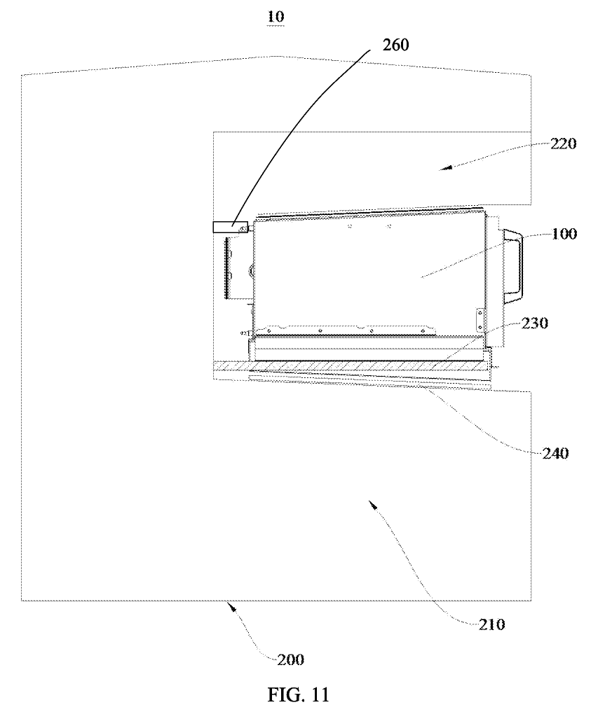

FIG. 11 is a schematic structural view of an electrical device according to an embodiment of the present disclosure.

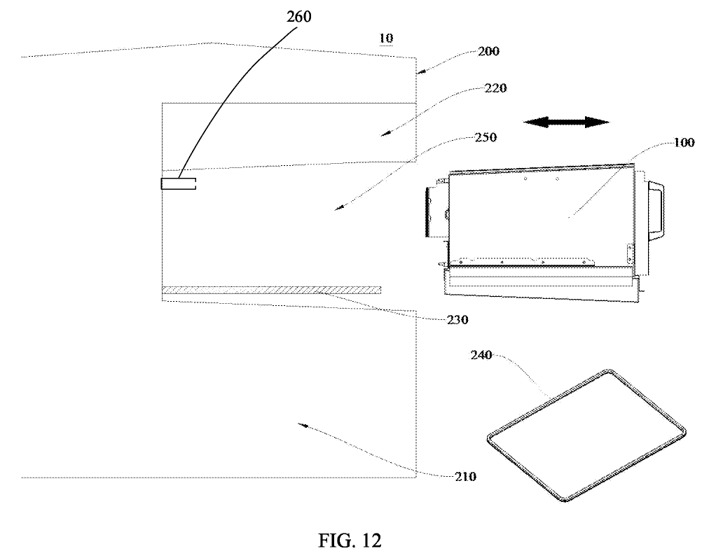

FIG. 12 is a schematic assembly view of an electrical device according to an embodiment of the present disclosure.

### Reference numerals of the accompanying drawings:

electrical device 10; power module 100, fifth positioning structure 140; base 110, first sliding structure 111, second sliding structure 112, base body 113, stop plate 114, second positioning structure 115, reinforcement member 116, ventilation opening 117, first sealing member 118, mounting part 1101; module body 120, heat sink 121, third sliding structure 122, first positioning structure 123, fourth positioning structure 124, first air opening 125, second air opening 126, second sealing member 127, power element 128; manipulation member 130, third positioning structure 131; cabinet 200, first air duct 210, second air duct 220, fourth sliding structure 230, third sealing member 240, mounting groove 250, sixth positioning structure 260.

### DETAILED DESCRIPTION OF THE EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

The present disclosure discloses a power module 100.

The power module 100 according to an embodiment of the present disclosure is described below with reference to FIG. 1 to FIG. 12.

In some embodiments, as illustrated in FIG. 1 to FIG. 6, the power module 100 includes a base 110 and a plurality of module bodies 120.

The base 110 may be provided with a plurality of mounting parts 1101 and a first sliding structure 111 configured to be slidably engaged with a cabinet 200. Each of the plurality of mounting parts may be provided with a second sliding structure 112. Each of the plurality of module bodies 120 may be provided with a third sliding structure 122 that may be slidably engaged with the second sliding structure 112. The plurality of module bodies 120 may be adapted to be mounted at the plurality of mounting parts via the third sliding structures 122, respectively.

“A plurality of” may be two or more. For example, in some embodiments, as illustrated in FIG. 1 and FIG. 2, three module bodies 120 are provided, and correspondingly, three mounting parts are also provided.

The first sliding structure 111 may include, but is not limited to, a slide block, a slide plate, a pulley, etc. For example, in some embodiments, as illustrated in FIG. 1 to FIG. 6, the first sliding structure 111 is a slide plate.

The third sliding structure 122 may include, but is not limited to, a slide block, a slide plate, a pulley, etc. For example, in some embodiments, as illustrated in FIG. 1 to FIG. 10, the third sliding structure 122 is a slide plate, and correspondingly, the second sliding structure 112 is a slide rail.

In actual operation, as illustrated in FIG. 1 to FIG. 6, when the plurality of module bodies 120 require overall maintenance, a relevant operator may pull the base 110 out of the cabinet 200 through the first sliding structure 111. In this case, the plurality of module bodies 120 mounted at the base 110 via the plurality of mounting parts are withdrawn together with the base. When a target module body 120 in the plurality of module bodies 120 requires independent maintenance, the relevant operator may individually pull the target module body 120 out of the base 110 through the third sliding structure 122 and the second sliding structure 112 that are slidably engaged with each other, disengaging the target module body 120 from the cabinet 200.

With the power module 100 according to the embodiments of the present disclosure, through the arrangement of the above-described first sliding structure 111, second sliding structure 112, and third sliding structure 122, the base 110 is slidably mounted at the cabinet 200 and the plurality of module bodies 120 are slidably mounted at the base 110. For users with different levels of professional expertise, the power module 100 supports overall mounting and disassembly while possessing a function of independent mounting and disassembly, providing a variety of maintenance methods for selection and further improving maintenance flexibility of the entire power module 100.

In some embodiments, as illustrated in FIG. 2 to FIG. 6, the base 110 may include a base body 113 and a stop plate 114.

The first sliding structure 111 and the second sliding structure 112 may be disposed at the base body 113. The stop plate 114 may be disposed at a back of the base body 113 and configured to stop the plurality of module bodies 120. Each of the plurality of module bodies 120 may be provided with a first positioning structure 123, and the stop plate 114 may be provided with a second positioning structure 115 engaged with the first positioning structure 123.

The first positioning structure 123 may be a positioning pin, a positioning shaft, a mandrel, etc., and the second positioning structure 115 may be a positioning hole. Alternatively, the first positioning structure 123 may be a positioning hole, and the second positioning structure 115 may be a positioning pin, a positioning shaft, a mandrel, etc. For example, in some embodiments, as illustrated in FIG. 2 to FIG. 6, the first positioning structure 123 may be a positioning pin, and the second positioning structure 115 may be a positioning hole.

A plurality of first positioning structures 123 and a plurality of second positioning structures 115 may be provided. “A plurality of” means two or more. For example, in some embodiments, as illustrated in FIG. 2 and FIG. 3, and FIG. 8 and FIG. 9, two first positioning structures 123 are provided, and correspondingly, two second positioning structures 115 are also provided.

In this embodiment, as illustrated in FIG. 2 to FIG. 6, when the module body 120 needs to be slidably mounted at the base body 113, the third sliding structure 122 of the module body 120 may be aligned with the second sliding structure 112 of the base 110. When the module body 120 slide to a mounting position in an extension direction of the second positioning structure 115, the first positioning structure 123 of the module body 120 may be slowly inserted rearward into the second positioning structure 115 of the stop plate 114. When the stop plate 114 abuts against the module body 120, the module body 120 has been pushed to a maximum depth.

In other embodiments, when the module body 120 needs to be slidably mounted at the base body 113, the third sliding structure 122 of the module body 120 may be aligned with the second sliding structure 112 of the base 110. When the module body 120 slide to the mounting position in the extension direction of the second positioning structure 115, the first positioning structure 123 of the module body 120 may be slowly fitted rearward into the second positioning structure 115 of the stop plate 114. When the stop plate 114 abuts against the module body 120, the module body 120 has been pushed to the maximum depth.

With the power module 100 according to the embodiments of the present disclosure, through the arrangement of the above-described stop plate 114, first positioning structure 123, and second positioning structure 115, limitation of a mounting depth of the module body 120 and positioning of the third sliding structure 122 and the second sliding structure 112 during sliding engagement are realized, which reduces a risk of derailment and jamming caused by mounting misalignment of the module body 120, improving mounting accuracy of the module body 120.

In some embodiments, as illustrated in FIG. 2 and FIG. 3, the base 110 may further include a reinforcement member 116 that may be mounted between the stop plate 114 and the base body 113.

In this embodiment, as illustrated in FIG. 2 and FIG. 3, the reinforcement member 116 is a triangular reinforcement rib. The reinforcement member 116 may be connected to the stop plate 114 by means of bolt connection, rivet connection, or other connection methods, and the reinforcement member 116 may be connected to the base body 113 by means of bolt connection, rivet connection, or other connection methods.

It should be understood that, if no reinforcement member 116 is disposed between the stop plate 114 and the base body 113, the stop plate 114 and the base body 113 are connected only by a fixing member at one side. When the module body 120 needs to be slidably mounted at the base body 113, the module body 120 slides rearward at a certain speed. When the module body 120 comes into contact with the stop plate 114, the module body 120 exerts a certain impact force on the stop plate 114. Over a long period of use, the fixing member between the stop plate 114 and the base body 113 may become loose or even fall off.

When the reinforcement member 116 is disposed between the stop plate 114 and the base body 113, the reinforcement member 116 can provide a supporting force on the stop plate 114. Even if the module body 120 impact the stop plate 114, the stop plate 114 can withstand a certain impact force under further reinforcement of the reinforcement member 116, improving stability and reliability of the connection between the stop plate 114 and the base body 113.

In some embodiments, as illustrated in FIG. 1 and FIG. 2, FIG. 4, and FIG. 11 and FIG. 12, the power module 100 may further include a manipulation member 130.

The manipulation member 130 may be detachably connected to the base 110 and the plurality of module bodies 120.

The manipulation member 130 may include a connection plate and a handle. The connection plate is configured to connect the base 110 and the plurality of module bodies 120. The handle may be mounted at a side of the connection plate facing away from the plurality of module bodies 120. One handle or a plurality of handles may be provided, and “a plurality of” means two or more. For example, in some embodiments, as illustrated in FIG. 2 and FIG. 3, two handles may be provided.

A connection method between the manipulation member 130 and the base 110 may include, but is not limited to, a threaded connection, a snap connection, or other detachable connection methods. For example, in some embodiments, the connection method between the manipulation member 130 and the base 110 is a threaded connection.

A connection method between the manipulation member 130 and the plurality of module bodies 120 may include, but is not limited to, a threaded connection, a snap connection, or other detachable connection methods. For example, in some embodiments, the connection method between the manipulation member 130 and the plurality of module bodies 120 is a threaded connection.

In actual operation, as illustrated in FIG. 1 and FIG. 2, FIG. 4, and FIG. 11 and FIG. 12, when the plurality of module bodies 120 require the overall maintenance, the relevant operator may pull the manipulation member 130 outwards to draw the base 110 out of the cabinet 200 through the first sliding structure 111. In this case, the plurality of module bodies 120 mounted at the base 110 via the plurality of mounting parts are withdrawn together with the base. When the target module body 120 in the plurality of module bodies 120 requires the independent maintenance, the relevant operator may first detach the manipulation member 130, and then individually pull the target module body 120 out of the base 110 through the third sliding structure 122 and the second sliding structure 112 that are slidably engaged with each other, disengaging the target module body 120 from the cabinet 200.

With the power module 100 according to the embodiments of the present disclosure, through the arrangement of the above-described manipulation member 130, overall modular mounting and disassembly of the plurality of module bodies 120 is realized. In addition, a handle structure is introduced to provide an optimal force application point, which makes it convenient for a user to grip during mounting and disassembly, reducing operation time required for the mounting and disassembly, and improving the maintainability and convenience of the entire power module 100.

In some embodiments, as illustrated in FIG. 2, the manipulation member 130 may be provided with third positioning structures 131. Each of the plurality of module bodies 120 may be provided with a fourth positioning structure 124 engaged with a respective one of the third positioning structures 131.

The third positioning structure 131 may be a positioning pin, a positioning shaft, a mandrel, etc., and the fourth positioning structure 124 may be a positioning hole. Alternatively, the third positioning structure 131 may be a positioning hole, and the fourth positioning structure 124 may be a positioning pin, a positioning shaft, a mandrel, etc. For example, in some embodiments, as illustrated in FIG. 2 to FIG. 6, the third positioning structure 131 may be a positioning hole, and the fourth positioning structure 124 may be a positioning pin.

In actual operation, as illustrated in FIG. 2, during assembly of the manipulation member 130, the third positioning structure 131 of the manipulation member 130 may be aligned with the fourth positioning structure 124 of the module body 120. After inserting the fourth positioning structure 124 of the module body 120 into the third positioning structure 131 of the manipulation member 130, the manipulation member 130 is connected to the module body 120 by means of bolt connection or other detachable connection methods, and the manipulation member 130 is connected to the base 110 by means of bolt connection or other detachable connection methods.

With the power module 100 according to the embodiments of the present disclosure, through the arrangement of the above-described third positioning structure 131 and fourth positioning structure 124, a positioning connection between the manipulation member 130 and the module body 120 is realized. Combined with the arrangement of the above-described first positioning structure 123 and second positioning structure 115, the accuracy of slidable engagement between the module body 120 and the base 110 is further improved.

In some embodiments, as illustrated in FIG. 2 and FIG. 3, each of the plurality of module bodies 120 may include a heat sink 121 and a power element 128 mounted at the heat sink 121. The heat sink 121 may have a first air opening 125 and a second air opening 126. The base 110 may have a ventilation opening 117 at each of the plurality of mounting parts. The first air opening 125 may be butted with the ventilation opening 117, and a first sealing member 118 may be disposed at the ventilation opening 117.

The power element 128 generates a large amount of heat during operating, and the heat sink 121 may be configured to cool and dissipate heat from the power element 128.

The first sealing member 118 may be a sealing strip. The first sealing member 118 may be made of plastic, rubber, silicone, etc. For example, in some embodiments, the first sealing member 118 is made of rubber. A rubber material may include, but is not limited to, nitrile rubber, fabric-reinforced rubber, fluororubber, etc.

When the first sealing member 118 is disposed at the ventilation opening 117, external air enters the heat sink 121 through the second air opening 126 and exits the heat sink 121 through the first air opening 125. At a position where the first air opening 125 is butted with the ventilation opening 117, the first sealing member 118 can effectively fill a gap between the first air opening 125 and the ventilation opening 117, preventing gas leakage between the heat sink 121 and the base 110. Therefore, contamination caused by leakage of dust carried by airflow in the air duct into the cabinet 200 is effectively reduced, improving airtightness between the heat sink 121 and the base 110 while enhancing protection capability of the entire electrical device 10.

In some embodiments, as illustrated in FIG. 4 and FIG. 10, the plurality of module bodies 120 may be slidably engaged with the base 110 in a first direction, and a plane where the first sealing member 118 is located extends in a second direction. An angle α between the first direction and the second direction may be an acute angle.

α may satisfy: 1°≤α≤30°. For example, in some embodiments, the angle α between the first direction and the second direction is 2.5°.

The first direction may be direction A as illustrated in FIG. 4 and FIG. 10, and the second direction may be direction B as illustrated in FIG. 4 and FIG. 10.

In actual operation, as illustrated in FIG. 4 to FIG. 6, the first direction may be the horizontal direction. When the module body 120 needs to be slidably mounted at the base body 113, the third sliding structure 122 of the module body 120 may be aligned with the second sliding structure 112 of the base 110, and the module body 120 may slide to the mounting position in the horizontal direction. During an entire sliding process, a beveled flange of the module body 120 at the first air opening 125 is butted with a beveled flange of the base 110 at the ventilation opening 117. Two sides of the first sealing member 118 are compressed uniformly and controllably by the module body 120 and the base 110, respectively. The first positioning structure 123 of the heat sink 121 may be slowly inserted rearward into the second positioning structure 115 of the stop plate 114. When the stop plate 114 abuts against the module body 120, the module body 120 has been pushed to the maximum depth.

With the power module 100 according to the embodiments of the present disclosure, through a structural design in which the angle α between the first direction and the second direction is the acute angle, a beveled flange butting between the module body 120 and the base 110 is achieved, in such a manner that the first sealing member 118 is compressed uniformly and controllably by the module body 120 and the base 110, further optimizing a sealing effect of the first sealing member 118. Combined with the design in which the first direction is a horizontal direction, assembly and disassembly operations are facilitated for the relevant operator. In addition, inclination is controlled within a reasonable range, improving a volume utilization rate of the entire power module 100.

In some embodiments, as illustrated in FIG. 1 to FIG. 10, each of the plurality of module bodies 120 may include a heat sink 121 and a power element 128 mounted at the heat sink 121. The heat sink 121 may have a first air opening 125 and a second air opening 126. The second air opening 126 may be configured to be butted with a second air duct 220 of the cabinet 200. A second sealing member 127 may be disposed at the second air opening 126.

The second sealing member 127 may be a sealing strip. The second sealing member 127 may be made of plastic, rubber, silicone, etc. For example, in some embodiments, the second sealing member 127 is made of rubber, and the rubber material may include, but is not limited to, nitrile rubber, fabric-reinforced rubber, fluororubber, etc.

When the second sealing member 127 is disposed at the second air opening 126, the external air enters the heat sink 121 through the second air opening 126. At a position where the second air opening 126 is butted with the second air duct 220, the second sealing member 127 can effectively fill a gap between the second air opening 126 and the second air duct 220, preventing gas leakage between an upper end of the heat sink 121 and the cabinet 200. Therefore, the contamination caused by leakage of dust carried by airflow in the air duct into the cabinet 200 is effectively reduced, improving airtightness between the upper end of the heat sink 21 and the cabinet 200 while enhancing the protection capability of the entire electrical device 10.

In some embodiments, as illustrated in FIG. 10, the plurality of module bodies 120 may be slidably engaged with the base 110 in a first direction, and a plane where the second sealing member 127 is located may extend in a third direction. An angle β between the third direction and the first direction may be an acute angle.

β satisfies: 1°≤β≤30°. For example, in some embodiments, the angle β between the third direction and the first direction is 2.5°.

The first direction may be direction A as illustrated in FIG. 10, and the third direction may be direction C as illustrated in FIG. 10.

In actual operation, as illustrated in FIG. 10 to FIG. 12, the first direction may be the horizontal direction. When the power module 100 needs to be slidably mounted at the cabinet 200, the base 110 and the module body 120 mounted at the base 110 may slide to the mounting position in the horizontal direction via the first sliding structure 111. During the entire sliding process, a beveled flange of the module body 120 at the second air opening 126 is butted with a beveled flange of the cabinet 200 at the second air duct 220. Two sides of the second sealing member 127 are compressed uniformly and controllably by the module body 120 and the cabinet 200, respectively.

With the power module 100 according to the embodiments of the present disclosure, through a structural design in which the angle β between the third direction and the first direction is the acute angle, a beveled flange butting between the upper end of the module body 120 and the cabinet 200 is achieved, in such a manner that the second sealing member 127 is compressed uniformly and controllably by the module body 120 and the cabinet 200, further optimizing a sealing effect of the second sealing member 127. Combined with the design in which the first direction is the horizontal direction, the assembly and disassembly operations are facilitated for the relevant operator. In addition, the inclination is controlled within the reasonable range, improving the volume utilization rate of the entire power module 100.

The present disclosure also discloses an electrical device 10.

In some embodiments, as illustrated in FIG. 11 and FIG. 12, the electrical device 10 includes a cabinet 200 and the power module 100 according to any one of the above-described embodiments.

The cabinet 200 has a mounting groove 250. A fourth sliding structure 230 is disposed in the mounting groove 250. The first sliding structure 111 is slidably engaged with the fourth sliding structure 230. The power module 100 is mounted in the mounting groove 250, and the base 110 is detachably connected to the cabinet 200.

The first sliding structure 111 may include, but is not limited to, a slide block, a slide plate, a pulley, etc. For example, in some embodiments, as illustrated in FIG. 11 and FIG. 12, the first sliding structure 111 is a slide plate, and the fourth sliding structure 230 is a slide rail.

The connection method between the base 110 and the cabinet 200 may include, but is not limited to, a threaded connection, a snap connection, or other detachable connection methods. For example, in some embodiments, the connection method between the base 110 and the cabinet 200 is a threaded connection.

In actual operation, as illustrated in FIG. 1 to FIG. 6, and FIG. 11 and FIG. 12, when the power module 100 is maintained, the detachable connection between the base 110 and the cabinet 200 may be released first. If the plurality of module bodies 120 require the overall maintenance, the relevant operator may pull the base 110 out of the mounting groove 250 of the cabinet 200 in the horizontal direction via the first sliding structure 111 and the fourth sliding structure 230 that are slidably engaged with each other. In this case, the plurality of module bodies 120 mounted at the base 110 via the plurality of mounting parts are withdrawn together with the base. If the target module body 120 in the plurality of module bodies 120 requires the independent maintenance, the relevant operator may pull the target module body 120 out of the base 110 in the horizontal direction via the third sliding structure 122 and the second sliding structure 112 that are slidably engaged with each other, disengaging the target module body 120 from the mounting groove 250 of the cabinet 200.

The electrical device 10 may include, but is not limited to, an inverter, a power converter, a transformer, etc., which is not limited herein. For example, in some embodiments, the electrical device 10 is an inverter.

With the electrical device 10 according to the present disclosure, through the arrangement of the above-described power module 100, compared with a solution in which multi-phase modules are individually mounted and maintained, the plurality of module bodies 120 are mounted at the base 110 to form an integrated combined module, which supports overall mounting and disassembly while possessing a function of independent mounting and disassembly, providing a variety of maintenance methods for selection and further improving maintenance flexibility of the entire power module 100.

In some embodiments, as illustrated in FIG. 4 to FIG. 6 and FIG. 10 to FIG. 12, the power module 100 may be provided with a fifth positioning structure 140 at a back of the power module 100, and the cabinet 200 may be provided with a sixth positioning structure 260 engaged with the fifth positioning structure 140.

The fifth positioning structure 140 may be a positioning pin, a positioning shaft, a mandrel, etc., and the sixth positioning structure may be a positioning hole. Alternatively, the fifth positioning structure 140 may be a positioning hole, and the sixth positioning structure may be a positioning pin, a positioning shaft, a mandrel, etc. For example, in some embodiments, as illustrated in FIG. 2 to FIG. 6, the fifth positioning structure 140 may be a positioning pin, and the sixth positioning structure may be a positioning hole.

A plurality of fifth positioning structures 140 and a plurality of sixth positioning structures may be provided, and “a plurality of” means two or more. For example, in some embodiments, as illustrated in FIG. 2 and FIG. 3, and FIG. 8 and FIG. 9, two fifth positioning structures 140 are provided, and correspondingly, two sixth positioning structures are also provided.

In actual operation, as illustrated in FIG. 4 to FIG. 6, and FIG. 10 to FIG. 12, the fifth positioning structure 140 may be disposed at each of the module body 120 and the base 110. When the power module 100 is slidably mounted in the cabinet 200, the first sliding structure 111 of the power module 100 may be aligned with the fourth sliding structure 230 of the cabinet 200. When the power module 100 slides to the mounting position in the horizontal direction, the fifth positioning structure 140 of the power module 100 may be slowly inserted rearward into the sixth positioning structure of the cabinet 200. In this case, radial displacement of the power module 100 along the fifth positioning structure 140 is restricted.

With the electrical device 10 according to the embodiments of the present disclosure, through the arrangement of the fifth positioning structure 140 and the sixth positioning structure, the positioning connection between the power module 100 and the cabinet 200 is realized, which improves the accuracy of the slidable engagement between the power module 100 and the cabinet 200, and restricts the radial displacement of the power module 100 along the fifth positioning structure 140. Combined with the multiple detachable connection methods, overall reliability and stability of the electrical device 10 are enhanced.

In some embodiments, as illustrated in FIG. 11 and FIG. 12, the cabinet 200 may have a first air duct 210 and a second air duct 220 that are separated. The first air duct 210 and the second air duct 220 may be open at different wall surfaces of the mounting groove 250. Each of the plurality of module bodies 120 may include a heat sink 121 and a power element 128 mounted at the heat sink 121. The heat sink 121 may have a first air opening 125 and a second air opening 126. The base 110 may have a ventilation opening 117. The first air duct 210 may be butted with the ventilation opening 117, the ventilation opening 117 may be butted with the first air opening 125, and the second air duct 220 may be butted with the second air opening 126. The first air duct 210 may be provided with a third sealing member 240.

The third sealing member 240 may be a sealing strip. The third sealing member 240 may be made of plastic, rubber, silicone, etc. For example, in some embodiments, the third sealing member 240 is made of rubber. The rubber material may include, but is not limited to, nitrile rubber, fabric-reinforced rubber, fluororubber, etc.

In this embodiment, as illustrated in FIG. 11 and FIG. 12, when the third sealing member 240 is disposed at the first air duct 210, the external air can enter the cabinet 200 through the second air duct 220, then enter the heat sink 121 through the second air opening 126, and exit the heat sink 121 through the first air opening 125, subsequently enter the base 110 through the ventilation opening 117, and finally exit the cabinet 200 through the first air duct 210. At a position where the first air opening 125 is butted with the first air duct 210, the third sealing member 240 can effectively fill a gap between the first air opening 125 and the first air duct 210, preventing gas leakage between a lower end of the heat sink 121 and the cabinet 200.

With the electrical device 10 according to the embodiments of the present disclosure, through the arrangement of the above-described third sealing member 240, the contamination caused by the leakage of the dust carried by the airflow in the air duct into the cabinet 200 is effectively reduced, which improves the airtightness between the lower end of the heat sink 121 and the cabinet 200 while enhancing the protection capability of the entire electrical device 10, prolonging a service life of the entire electrical device 10.

In some embodiments, as illustrated in FIG. 4, the plurality of module bodies 120 is slidably engaged with the base 110 in a first direction, and a plane the third sealing member 240 is located extends in a fourth direction. An angle γ between the fourth direction and the first direction may be an acute angle.

γ satisfies: 1°≤γ≤30°, and the angle γ between the fourth direction and the first direction may be equal to the angle α between the first direction and the second direction. For example, in some embodiments, the angle α between the first direction and the second direction is 2.5°, and correspondingly, the angle γ between the fourth direction and the first direction is also 2.5°.

The first direction may be direction A as illustrated in FIG. 4, and the fourth direction may be direction D as illustrated in FIG. 4.

In actual operation, as illustrated in FIG. 10 to FIG. 12, the first direction may be the horizontal direction. When the power module 100 needs to be slidably mounted at the cabinet 200, the power module 100 may slide to the mounting position in the horizontal direction via the first sliding structure 111 and the fourth sliding structure 230 that are slidably engaged with each other. During the entire sliding process, the beveled flange of the module body 120 at the first air opening 125 is butted with the beveled flange of the cabinet 200 at the first air duct 210. Two sides of the third sealing member 240 are compressed uniformly and controllably by the module body 120 and the cabinet 200, respectively.

With the electrical device 10 according to the embodiments of the present disclosure, through a structural design in which the angle γ between the fourth direction and the first direction is the acute angle, a beveled flange butting between the lower end of the module body 120 and the cabinet 200 is achieved, in such a manner that the third sealing member 240 is compressed uniformly and controllably by the module body 120 and the cabinet 200, further optimizing a sealing effect of the third sealing member 240. Combined with the design in which the first sliding structure 111 is slidably engaged with the fourth sliding structure 230 in the horizontal direction, the assembly and disassembly operations are facilitated for the relevant operator. In addition, the inclination is controlled within the reasonable range, improving the volume utilization rate of the entire power module 100.

Terms “first”, “second” and the like in the specification and claims of the present disclosure are used to distinguish similar objects, rather than to describe a specific sequence or order. It should be understood that data used in this way may be interchanged with each other under appropriate circumstances, such that the embodiments of the present disclosure can be implemented in a sequence other than those illustrated or described in the present disclosure. Further, that objects distinguished by “first”, “second”, etc. generally belong to one class, and the number of objects is not limited. For example, one or more of the first object can be provided. In addition, “and/or” in the description and claims represents at least one of the correlated objects, and the symbol “/” generally indicates an “or” relationship between the correlated objects preceding and succeeding the symbol.

In the description of the present disclosure, it should be understood that the orientation or the position indicated by terms such as “over”, “below”, “front”, “rear”, “vertical”, “horizontal”, “top”, “bottom”, “inner”, “outer”, “axial”, “radial”, and “circumferential” should be construed to refer to the orientation or the position as shown in the drawings, and is only for the convenience of describing the present disclosure and simplifying the description, rather than indicating or implying that the pointed device or element must have a specific orientation, or be constructed and operated in a specific orientation, and therefore cannot be understood as a limitation to the present disclosure.

In the description of the present disclosure, “first feature” and “second feature” may include one or more this feature.

In the description of the present disclosure, “plurality” means two or more.

In the description of the present disclosure, the first feature being “on” or “under” the second feature may include the first feature being in direct contact with the second feature, or the first feature being not in direct contact with the second feature, but being in contact with the second feature through another feature therebetween.

In the description of the present disclosure, the first feature being “above” the second feature includes the first feature being directly above or obliquely above the second feature, or simply means that a level of the first feature is higher than a level of the second feature.

Reference throughout this specification to “an embodiment”, “some embodiments”, “schematic embodiments”, “an example”, “a specific example”, or “some examples” means that a particular feature, structure, material, or characteristic described in connection with the embodiment or example is included in at least one embodiment or example of the present disclosure. In this specification, exemplary descriptions of aforesaid terms are not necessarily referring to the same embodiment or example. Further, the particular features, structures, materials, or characteristics can be combined in any suitable manner in one or more embodiments or examples.

Although embodiments of the present disclosure have been illustrated and described, it is conceivable for those of ordinary skill in the art that various changes, modifications, replacements, and variations can be made to these embodiments without departing from the principles and spirit of the present disclosure. The scope of the present disclosure shall be defined by the claims as appended and their equivalents.

What is claimed is:

1. A power module, comprising:
a base provided with a plurality of mounting parts and a first sliding structure configured to be slidably engaged with a cabinet, wherein each of the plurality of mounting parts is provided with a second sliding structure; and
a plurality of module bodies, wherein each of the plurality of module bodies is provided with a third sliding structure slidably engaged with the second sliding structure, the plurality of module bodies being adapted to be mounted at the plurality of mounting parts via the third sliding structures, respectively.

2. The power module according to claim 1, wherein the base comprises:
a base body, wherein the first sliding structure and the second sliding structure are disposed at the base body; and
a stop plate disposed at a back of the base body and configured to stop the plurality of module bodies, wherein each of the plurality of module bodies is provided with a first positioning structure, and the stop plate is provided with a second positioning structure engaged with the first positioning structure.

3. The power module according to claim 2, wherein the base further comprises a reinforcement member mounted between the stop plate and the base body.

4. The power module according to claim 1, further comprising:
a manipulation member detachably connected to the base and the plurality of module bodies.

5. The power module according to claim 4, wherein the manipulation member is provided with third positioning structures, and each of the plurality of module bodies is provided with a fourth positioning structure engaged with a respective one of the third positioning structures.

6. The power module according to claim 1, wherein:
each of the plurality of module bodies comprises a heat sink and a power element mounted at the heat sink, the heat sink having a first air opening and a second air opening; and
the base has a ventilation opening at each of the plurality of mounting parts, the first air opening being butted with the ventilation opening, and a first sealing member being disposed at the ventilation opening.

7. The power module according to claim 6, wherein the plurality of module bodies is slidably engaged with the base in a first direction, and a plane where the first sealing member is located extends in a second direction, an angle between the first direction and the second direction being an acute angle.

8. The power module according to claim 1, wherein each of the plurality of module bodies comprises a heat sink and a power element mounted at the heat sink, the heat sink having a first air opening and a second air opening, wherein the second air opening is configured to be butted with a second air duct of the cabinet, and wherein a second sealing member is disposed at the second air opening.

9. The power module according to claim 8, wherein the plurality of module bodies is slidably engaged with the base in a first direction, and a plane where the second sealing member is located extends in a third direction, an angle between the third direction and the first direction being an acute angle.

10. An electrical device, comprising:
the power module according to claim 1; and
a cabinet having a mounting groove, wherein a fourth sliding structure is disposed in the mounting groove, the first sliding structure being slidably engaged with the fourth sliding structure, the power module being mounted in the mounting groove, and the base being detachably connected to the cabinet.

11. The electrical device according to claim 10, wherein the power module is provided with a fifth positioning structure at a back of the power module, and the cabinet is provided with a sixth positioning structure engaged with the fifth positioning structure.

12. The electrical device according to claim 10, wherein:
the cabinet has a first air duct and a second air duct that are open at different wall surfaces of the mounting groove;
each of the plurality of module bodies comprises a heat sink and a power element mounted at the heat sink, the heat sink having a first air opening and a second air opening;
the base has a ventilation opening, the first air duct being butted with the ventilation opening, and the ventilation opening being butted with the first air opening;
the second air duct is butted with the second air opening; and
the first air duct is provided with a third sealing member.

13. The electrical device according to claim 12, wherein the plurality of module bodies is slidably engaged with the base in a first direction, and a plane where the third sealing member is located extends in a fourth direction, an angle between the fourth direction and the first direction being an acute angle.

14. The electrical device according to claim 10, wherein the base comprises:
a base body, wherein the first sliding structure and the second sliding structure are disposed at the base body; and
a stop plate disposed at a back of the base body and configured to stop the plurality of module bodies, wherein each of the plurality of module bodies is provided with a first positioning structure, and the stop plate is provided with a second positioning structure engaged with the first positioning structure.

15. The electrical device according to claim 14, wherein the base further comprises a reinforcement member mounted between the stop plate and the base body.

16. The electrical device according to claim 10, further comprising:
a manipulation member detachably connected to the base and the plurality of module bodies.

17. The electrical device according to claim 16, wherein the manipulation member is provided with third positioning structures, and each of the plurality of module bodies is provided with a fourth positioning structure engaged with a respective one of the third positioning structures.

18. The electrical device according to claim 10, wherein:
each of the plurality of module bodies comprises a heat sink and a power element mounted at the heat sink, the heat sink having a first air opening and a second air opening; and
the base has a ventilation opening at each of the plurality of mounting parts, the first air opening being butted with the ventilation opening, and a first sealing member being disposed at the ventilation opening.

19. The electrical device according to claim 18, wherein the plurality of module bodies is slidably engaged with the base in a first direction, and a plane where the first sealing member is located extends in a second direction, an angle between the first direction and the second direction being an acute angle.

20. The electrical device according to claim 10, wherein each of the plurality of module bodies comprises a heat sink and a power element mounted at the heat sink, the heat sink having a first air opening and a second air opening, wherein the second air opening is configured to be butted with a second air duct of the cabinet, and wherein a second sealing member is disposed at the second air opening.
